(19) United States
(12) Patent Application Publication
(10) Pub. No.: US 2022/0368284 A1
(43) Pub. Date: Nov. 17, 2022

(54) POWER AMPLIFICATION CIRCUIT, RADIO-FREQUENCY CIRCUIT, AND COMMUNICATION DEVICE

(71) Applicant: Murata Manufacturing Co., Ltd., Kyoto (JP)

(72) Inventors: Kenji TAHARA, Kyoto (JP); Yusuke TANAKA, Kyoto (JP); Yoshiaki SUKEMORI, Kyoto (JP)

(21) Appl. No.: 17/815,288

(22) Filed: Jul. 27, 2022

Related U.S. Application Data
(63) Continuation of application No. PCT/JP2020/041757, filed on Nov. 9, 2020.

(30) Foreign Application Priority Data
Mar. 12, 2020 (JP) 2020-043530

(51) Int. Cl. H03F 1/02; H03F 3/24

(52) U.S. Cl. CPC H03F 1/0238; H03F 3/245; H03F 2200/451

(57) ABSTRACT

A current flowing through a transistor of a final-stage amplifier is suppressed. A power amplification circuit includes a driving-stage amplifier, a final-stage amplifier, a power supply terminal, a first voltage control circuit, and a second voltage control circuit. The driving-stage amplifier includes a first transistor having a first input terminal, a first output terminal, and a first ground terminal. The final-stage amplifier includes a second transistor having a second input terminal, a second output terminal, and a second ground terminal. The first voltage control circuit is connected between the power supply terminal and the first output terminal, and controls a first power supply voltage applied to the first transistor. The second voltage control circuit is connected between the power supply terminal and the second output terminal, and controls a second power supply voltage applied to the second transistor.

### CROSS REFERENCE TO RELATED APPLICATION

This is a continuation of International Application No. PCT/JP2020/041757 filed on Nov. 9, 2020 which claims priority from Japanese Patent Application No. 2020-043530 filed on Mar. 12, 2020. The contents of these applications are incorporated herein by reference in their entireties.

### BACKGROUND ART

### Technical Field

The present disclosure generally relates to a power amplification circuit, a radio-frequency circuit, and a communication device, and, more specifically, relates to a power amplification circuit which power-amplifies radio-frequency signals, a radio-frequency circuit which includes the power amplification circuit, and a communication device which includes the radio-frequency circuit.

A known device in the related art is an RF power amplification device including a driver-stage amplifier, a first RF amplifier, a second RF amplifier, and a DC voltage converter (for example, see Patent Document 1).

Patent Document 1 describes an RF power amplification device in which a driver-stage amplifier, a first RF amplifier, a second RF amplifier, and a DC voltage converter are operable with external power supply voltages supplied from the outside of the RF power amplification device.

An output signal, which is generated from the output terminal of the driver-stage amplifier, may be supplied to the input terminal of the first RF amplifier and the input terminal of the second RF amplifier. Through supply of an external power supply voltage to the DC voltage converter, the DC voltage converter may generate an operating power supply voltage lower than the external power supply voltage. The operating power supply voltage may be supplied to the output terminal of the second RF amplifier. The output terminal of the first RF amplifier may be supplied, not through the DC voltage converter, with an external power supply voltage supplied from the outside of the RF power amplification device.

Each of the driver-stage amplifier, the first RF amplifier, and the second RF amplifier is formed of either one of a field-effect transistor and a bipolar transistor.

Patent Document 1: Japanese Unexamined Patent Application Publication No. 2011-259083

### BRIEF SUMMARY

The RF power amplification device described in Patent Document 1 has a problem in that, in operation with low output power (in low power), a large current flows through the transistor (a field-effect transistor or a bipolar transistor) of the second RF amplifier.

The present disclosure provides a power amplification circuit, a radio-frequency circuit, and a communication device which enable suppression of the current flowing through a transistor of a final-stage amplifier.

A power amplification circuit according to an aspect of the present disclosure power-amplifies a radio-frequency signal. The power amplification circuit includes a driving-stage amplifier, a final-stage amplifier, a power supply terminal, a first voltage control circuit, and a second voltage control circuit. The driving-stage amplifier includes a first transistor having a first input terminal, a first output terminal, and a first ground terminal. The final-stage amplifier includes a second transistor having a second input terminal, a second output terminal, and a second ground terminal. The second input terminal is connected to the first output terminal. The first voltage control circuit is connected between the power supply terminal and the first output terminal, and controls a first power supply voltage applied to the first transistor. The second voltage control circuit is a circuit different from the first voltage control circuit. The second voltage control circuit is connected between the power supply terminal and the second output terminal. The second voltage control circuit controls a second power supply voltage applied to the second transistor.

A radio-frequency circuit according to an aspect of the present disclosure includes the power amplification circuit and a filter. The filter passes the radio-frequency signal which is power-amplified by the power amplification circuit and which is output from the power amplification circuit.

A communication device according to an aspect of the present disclosure includes the radio-frequency circuit and a signal processing circuit. The signal processing circuit outputs a radio-frequency signal to the power amplification circuit.

The power amplification circuit, the radio-frequency circuit, and the communication device according to the aspects of the present disclosure enable suppression of the current flowing through the second transistor of the final-stage amplifier.

### BRIEF DESCRIPTION OF THE DRAWINGS

FIG. 1 is a circuit diagram of a power amplification circuit according to a first embodiment.

FIG. 2 is a circuit diagram of a communication device including the power amplification circuit.

FIG. 3 is a circuit diagram of a first voltage control circuit in the power amplification circuit.

FIG. 4 is a circuit diagram of a second voltage control circuit in the power amplification circuit.

FIG. 5 is a circuit diagram of bias circuits in the power amplification circuit.

FIG. 6 is a characteristics diagram, of the power amplification circuit, which illustrates the relationship between control voltage and idle currents.

FIG. 7 is a characteristics diagram, of the power amplification circuit, which illustrates the relationship between control voltage and output power and the relationship between control voltage and collector current.

FIG. 8 is a characteristics diagram, of a power amplification circuit according to a comparison example of the first embodiment, which illustrates the relationship between control voltage and idle currents.

FIG. 9 is a characteristics diagram, of the power amplification circuit according the comparison example, which illustrates the relationship between control voltage and output power and the relationship between control voltage and collector current.

FIG. 10 is a circuit diagram of another configuration example of the second voltage control circuit of the power amplification circuit according to the first embodiment.

FIG. 11 is a circuit diagram of another configuration example of the first voltage control circuit of the power amplification circuit according to the first embodiment.

FIG. 12 is a circuit diagram of a power amplification circuit according to a second embodiment.

FIG. 13 is a circuit diagram of a power amplification circuit according to a third embodiment.

FIG. 14 is a circuit diagram of a power amplification circuit according to a fourth embodiment.

### DETAILED DESCRIPTION

### First Embodiment

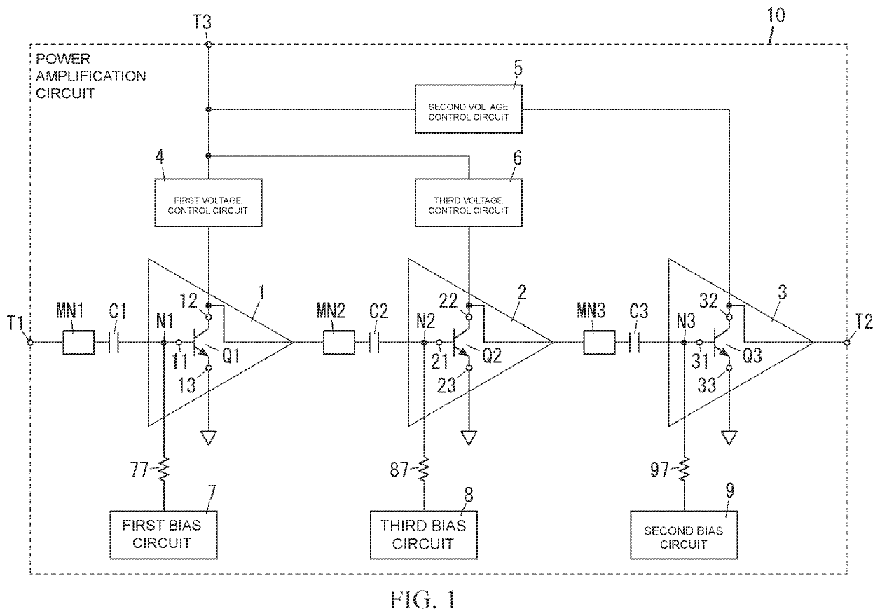

A power amplification circuit 10 according to a first embodiment will be described below by referring to FIGS. 1 to 5.

### (1) A Power Amplification Circuit, a Radio-Frequency Circuit, and a Communication Device

### (1.1) The Circuit Configuration of a Radio-Frequency Circuit Including a Power Amplification Circuit

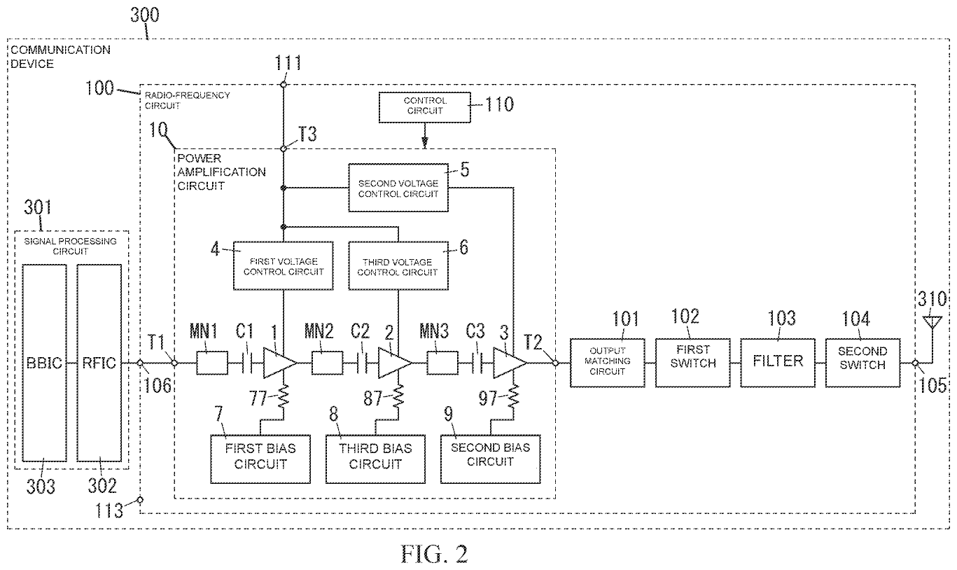

As illustrated in FIG. 2, a radio-frequency circuit 100 including the power amplification circuit 10 is used, for example, in a communication device 300. The communication device 300 is, for example, a cellular phone (for example, a smartphone), but is not limited to this. For example, the communication device 300 may be a wearable terminal (for example, a smartwatch). The radio-frequency circuit 100 is a circuit, for example, compatible with a 4G (fourth generation mobile communication) standard or a 5G (fifth generation mobile communication) standard. Such a 4G standard is, for example, the 3GPP LTE (Long Term Evolution) standard. Such a 5G standard is, for example, 5G NR (New Radio). The radio-frequency circuit 100 may be a circuit compatible with carrier aggregation and dual connectivity.

For example, the radio-frequency circuit 100 amplifies radio-frequency signals (transmit signals) received from a signal processing circuit 301, and outputs the amplified signals to an antenna 310. The signal processing circuit 301 is not a component of the radio-frequency circuit 100, and is a component of the communication device 300 including the radio-frequency circuit 100. The radio-frequency circuit 100 is controlled, for example, by the signal processing circuit 301 included in the communication device 300.

The radio-frequency circuit 100 includes the power amplification circuit 10, an output matching circuit 101, a first switch 102, a filter 103, a second switch 104, an antenna terminal 105, a radio-frequency signal input terminal 106, and a terminal-for-power-supply 111.

For example, the power amplification circuit 10 amplifies, for output, input signals from the signal processing circuit 301. The input signals are radio-frequency signals (transmit signals) in a given frequency band. For example, the given frequency band includes multiple communication bands different from each other.

As illustrated in FIGS. 1 and 2, the power amplification circuit 10 includes a driving-stage amplifier 1, a final-stage amplifier 3, a power supply terminal T3, a first voltage control circuit 4, and a second voltage control circuit 5. The power amplification circuit 10 further includes an interstage amplifier 2 connected between the driving-stage amplifier 1 and the final-stage amplifier 3. The power amplification circuit 10 further includes a third voltage control circuit 6. The driving-stage amplifier 1 includes a first transistor Q1. The final-stage amplifier 3 includes a second transistor Q3. The interstage amplifier 2 includes a third transistor Q2. The first voltage control circuit 4 controls a first power supply voltage Vcc1 applied to the first transistor Q1. The second voltage control circuit 5 controls a second power supply voltage Vcc2 applied to the second transistor Q3. The third voltage control circuit 6 controls a third power supply voltage Vcc3 applied to the third transistor Q2.

The power amplification circuit 10 also includes a first bias circuit 7, a second bias circuit 9, and a third bias circuit 8. The first bias circuit 7 is connected to the first transistor Q1 of the driving-stage amplifier 1. The second bias circuit 9 is connected to the second transistor Q3 of the final-stage amplifier 3. The third bias circuit 8 is connected to the third transistor Q2 of the interstage amplifier 2.

The output matching circuit 101 is disposed on the signal path between the power amplification circuit 10 and the first switch 102. The output matching circuit 101 is a circuit for impedance matching between the power amplification circuit 10 and the filter 103. The output matching circuit 101 is formed, for example, of a single inductor. However, the configuration is not limited to this. For example, the output matching circuit 101 may include multiple inductors and multiple capacitors.

The first switch 102 is disposed between the output matching circuit 101 and the filter 103. The first switch 102 has a common terminal and multiple selection terminals. The first switch 102 is connected, at the common terminal, to the power amplification circuit 10 through the output matching circuit 101. The first switch 102 is connected to the filter 103 at one of the selection terminals. The first switch 102 is, for example, a switch capable of connecting the common terminal to at least one of the selection terminals. The first switch 102 is, for example, a switch enabling one-to-one connection and one-to-many connection. The first switch 102 is a switch capable of switching between signal paths for transmit signals having communication bands different from each other. The first switch 102 switches the connection state between the common terminal and the selection terminals, for example, in accordance with a control signal received from the signal processing circuit 301. The first switch 102 is, for example, a switch IC (Integrated Circuit). The first switch 102 may have any configuration as long as the connection state between the common terminal and the selection terminals is switched, for example, in accordance a digital control signal received from the signal processing circuit 301.

The filter 103 is a filter whose passband is the transmit band of one (for example, Band3) of the communication bands described above. The filter 103 is, for example, a single chip having an acoustic wave filter including multiple serial arm resonators and multiple parallel arm resonators, each of which is formed of an acoustic wave resonator. Such an acoustic wave filter is, for example, a surface acoustic wave filter using surface acoustic waves. The surface acoustic wave filter has multiple serial arm resonators and multiple parallel arm resonators, each of which is, for example, a SAW (Surface Acoustic Wave) resonator. The filter 103 is not limited to a single chip having an acoustic wave filter, and, for example, may have a package structure.

The second switch 104 is disposed between the filter 103 and the antenna terminal 105. The second switch 104 is a switch connected to the antenna terminal 105. The second switch 104 has a common terminal and multiple selection terminals. The second switch 104 is connected to the antenna terminal 105 at the common terminal. The second switch 104 is connected to the filter 103 at one of the selection terminals. The second switch 104 switches the connection state between the common terminal and the selection terminals, for example, in accordance with a control signal received from the signal processing circuit 301. The second switch 104 is, for example, a switch IC. The second switch 104 may have any configuration as long as the connection state between the common terminal and the selection terminals is switched, for example, in accordance with a digital control signal received from the signal processing circuit 301.

The antenna terminal 105 is connected to the antenna 310. The antenna 310 is not a component of the radio-frequency circuit 100, and is a component of the communication device 300.

In the radio-frequency circuit 100, a radio-frequency signal (transmit signal), which is output from the power amplification circuit 10, is transmitted from the antenna 310 through the output matching circuit 101, the first switch 102, the filter 103, the second switch 104, and the antenna terminal 105.

In the radio-frequency circuit 100, the terminal-for-power-supply 111 is connected to the driving-stage amplifier 1, the interstage amplifier 2, and the final-stage amplifier 3 through the power supply terminal T3. In the power amplification circuit 10, the power supply terminal T3 is connected to the first transistor Q1 of the driving-stage amplifier 1 through the first voltage control circuit 4. The power supply terminal T3 is connected to the second transistor Q3 of the final-stage amplifier 3 through the second voltage control circuit 5. The power supply terminal T3 is connected to the third transistor Q2 of the interstage amplifier 2 through the third voltage control circuit 6. The power supply terminal T3 is supplied with a power supply voltage Vbat through the terminal-for-power-supply 111 from a battery. The power supply voltage Vbat is, for example, 4 V. The battery is, for example, a power supply battery for the communication device 300. The terminal-for-power-supply 111 is connected to the battery terminal of the communication device 300. The battery is neither a component of the power amplification circuit 10, that of the radio-frequency circuit 100, nor that of the communication device 300. However, the configuration is not limited to this. The battery may be a component of the communication device 300.

### (1.2) The Circuit Configuration of the Communication Device Including the Radio-Frequency Circuit

The communication device 300 includes the radio-frequency circuit 100 and the signal processing circuit 301. The communication device 300 further includes the antenna 310. The signal processing circuit 301 includes, for example, an RF-signal processing circuit 302 and a baseband-signal processing circuit 303. The RF-signal processing circuit 302 is, for example, an RFIC (Radio Frequency Integrated Circuit), and performs signal processing on a radio-frequency signal. For example, the RF-signal processing circuit 302 performs signal processing, such as upconverting, on a radio-frequency signal (transmit signal), which is output from the baseband-signal processing circuit 303, and outputs the radio-frequency signal having been subjected to the signal processing. The baseband-signal processing circuit 303 is, for example, a BBIC (Baseband Integrated Circuit). The baseband-signal processing circuit 303 generates an I-phase signal and a Q-phase signal from a baseband signal. A baseband signal is, for example, an audio signal or an image signal received from the outside. The baseband-signal processing circuit 303 performs IQ modulation by synthesizing an I-phase signal and a Q-phase signal, and outputs a transmit signal. At that time, a transmit signal is generated as a modulated signal (IQ signal) obtained through amplitude modulation of a carrier-wave signal, having a given frequency, with a period longer than that of the carrier-wave signal. The radio-frequency circuit 100 transmits a radio-frequency signal (transmit signal) between the antenna 310 and the RF-signal processing circuit 302 of the signal processing circuit 301.

In the power amplification circuit 10, for example, as a control voltage Vramp from the signal processing circuit 301 increases, the output power Pout increases. The control voltage Vramp is, for example, equal to or higher than 0 V and equal to or lower than 2 V.

The power amplification circuit 10 according to the first embodiment includes the first voltage control circuit 4, which is connected between the power supply terminal T3 and the first transistor Q1, and the second voltage control circuit 5, which is different from the first voltage control circuit 4 and is connected between the power supply terminal T3 and the second transistor Q3. In the power amplification circuit 10, the first voltage control circuit 4 controls the first power supply voltage Vcc1 applied to the first transistor Q1; the second voltage control circuit 5 controls the second power supply voltage Vcc2 applied to the second transistor Q3. Thus, the power amplification circuit 10 according to the first embodiment enables suppression of the current flowing through the second transistor Q3 of the final-stage amplifier 3. In the power amplification circuit 10 according to the first embodiment, the input power of the second transistor Q3 may be increased when the second power supply voltage Vcc2 for the second transistor Q3 is relatively low, and the efficiency of the second transistor Q3 may be increased, achieving suppression of the current flowing through the second transistor Q3 in operation with relatively low output power Pout (in low power).

### (1.3) The Circuit Configuration of the Power Amplification Circuit

The power amplification circuit 10 includes the driving-stage amplifier 1, the final-stage amplifier 3, the interstage amplifier 2, the power supply terminal T3, the first voltage control circuit 4, the second voltage control circuit 5, and the third voltage control circuit 6. The power amplification circuit 10 further includes a signal input terminal T1, a signal output terminal T2, the first bias circuit 7, the second bias circuit 9, the third bias circuit 8, a first matching circuit MN1, a second matching circuit MN3, and a third matching circuit MN2.

As illustrated in FIG. 1, in the power amplification circuit 10, the driving-stage amplifier 1, the final-stage amplifier 3, and the interstage amplifier 2 include the first transistor Q1, the second transistor Q3, and the third transistor Q2. The first transistor Q1, the second transistor Q3, and the second transistor Q3 are amplifier transistors which power-amplify radio-frequency signals.

Each of the first transistor Q1, the second transistor Q3, and the third transistor Q2 is, for example, a bipolar transistor. Each of the first transistor Q1, the second transistor Q3, and the third transistor Q2 is an npn bipolar transistor.

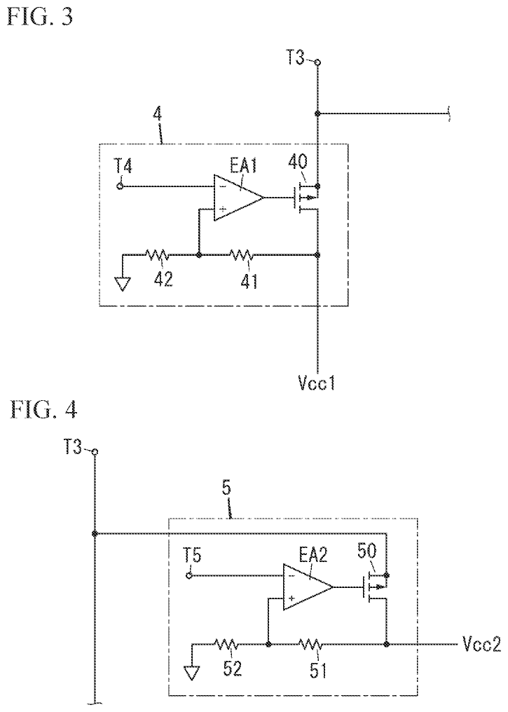

The first transistor Q1 has a first input terminal 11, a first output terminal 12, and a first ground terminal 13. In the first transistor Q1, the first input terminal 11, the first output terminal 12, and the first ground terminal 13 are a first base terminal, a first collector terminal, and a first emitter terminal, respectively. The first transistor Q1 is connected to the signal input terminal T1 at the first input terminal 11. The first transistor Q1 is connected to the ground at the first ground terminal 13. The first transistor Q1 is connected, at the first output terminal 12, to the power supply terminal T3 through the first voltage control circuit 4. The first power supply voltage Vcc1 (see FIG. 3) is applied from the first voltage control circuit 4 to the first transistor Q1 (between the first output terminal 12 and the first ground terminal 13). The first transistor Q1 amplifies a radio-frequency signal received at the first input terminal 11, and outputs the amplified signal from the first output terminal 12.

The second transistor Q3 has a second input terminal 31, a second output terminal 32, and a second ground terminal 33. In the second transistor Q3, the second input terminal 31, the second output terminal 32, and the second ground terminal 33 are a second base terminal, a second collector terminal, and a second emitter terminal, respectively. The second transistor Q3 is connected, at the second input terminal 31, to the first output terminal 12 of the first transistor Q1 of the driving-stage amplifier 1. More specifically, the second transistor Q3 is connected, at the second input terminal 31, to the first output terminal 12 of the first transistor Q1 of the driving-stage amplifier 1 through the third transistor Q2 of the interstage amplifier 2. The second transistor Q3 is connected, at the second output terminal 32, to the power supply terminal T3 through the second voltage control circuit 5. The second power supply voltage Vcc2 (see FIG. 4) is applied from the second voltage control circuit 5 to the second transistor Q3 (between the second output terminal 32 and the second ground terminal 33). The second transistor Q3 amplifies a radio-frequency signal received at the second input terminal 31, and outputs the amplified signal from the second output terminal 32.

The third transistor Q2 has a third input terminal 21, a third output terminal 22, and a third ground terminal 23. In the third transistor Q2, the third input terminal 21, the third output terminal 22, and the third ground terminal 23 are a third base terminal, a third collector terminal, and a third emitter terminal, respectively. The third transistor Q2 is connected, at the third input terminal 21, to the first output terminal 12 of the first transistor Q1. The third transistor Q2 is connected, at the third output terminal 22, to the second input terminal 31 of the second transistor Q3. The third transistor Q2 is connected to the ground at the third ground terminal 23. The third transistor Q2 is connected, at the third output terminal 22, to the power supply terminal T3 through the third voltage control circuit 6. The third power supply voltage Vcc3 is applied from the third voltage control circuit 6 to the third transistor Q2 (between the third output terminal 22 and the third ground terminal 23). The third transistor Q2 amplifies a radio-frequency signal received at the third input terminal 21, and outputs the amplified signal from the third output terminal 22.

The signal input terminal T1 is a terminal receiving a radio-frequency signal. More specifically, the signal input terminal T1 is, for example, a terminal receiving a radio-frequency signal from the signal processing circuit 301, through the radio-frequency signal input terminal 106 of the radio-frequency circuit 100. In the power amplification circuit 10, the signal input terminal T1 is connected to the first input terminal 11 of the first transistor Q1 of the driving-stage amplifier 1.

The signal output terminal T2 is a terminal which outputs a radio-frequency signal amplified in the power amplification circuit 10. In the power amplification circuit 10, the signal output terminal T2 is connected to the second output terminal 32 of the second transistor Q3 of the final-stage amplifier 3.

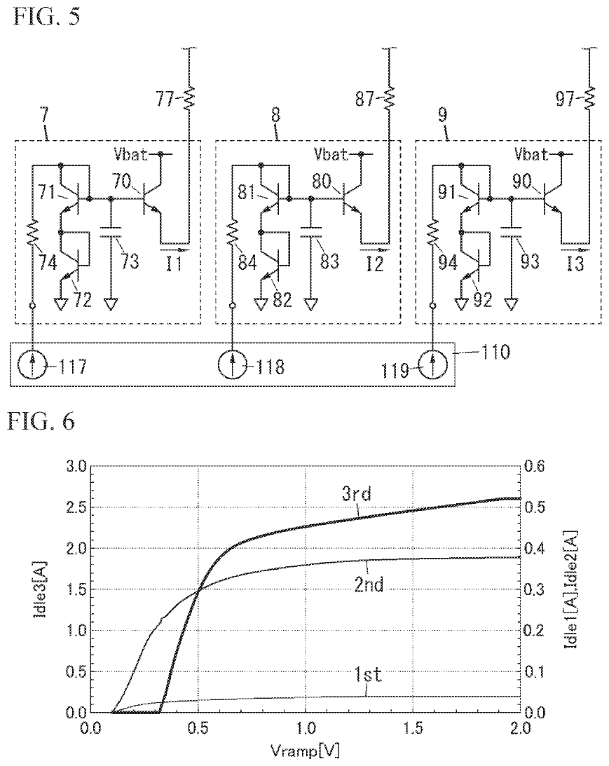

The first bias circuit 7 is connected to the first input terminal 11 of the first transistor Q1. The first bias circuit 7 supplies a first bias to the first transistor Q1. More specifically, the first bias circuit 7 supplies a first bias current I1 (see FIG. 5) to the first input terminal 11 of the first transistor Q1.

As illustrated in FIG. 5, the first bias circuit 7 includes a transistor 70. The transistor 70 has a control terminal, a first main terminal, and a second main terminal. The transistor 70 is, for example, an npn bipolar transistor. In this case, the control terminal, the first main terminal, and the second main terminal in the transistor 70 are its base, its collector, and its emitter, respectively. The transistor 70 is connected, at its collector, to the power supply terminal T3, and is connected, at its emitter, to the first input terminal 11 of the first transistor Q1. More specifically, the transistor 70 is connected, at its emitter, to the first input terminal 11 of the first transistor Q1 through a resistor 77. As described above, the power supply terminal T3 is supplied, for example, with the power supply voltage Vbat from the battery. The first bias current I1, which is output from the first bias circuit 7, is supplied to the first input terminal 11 of the first transistor Q1 through the resistor 77. The first bias current I1 is a direct current which determines the operating point of the first transistor Q1. In the first bias circuit 7, the transistor 70 is used as an emitter-follower transistor. The transistor 70 is a transistor for amplifying a current.

The first bias circuit 7 includes two diodes 71 and 72, a capacitor 73, and a resistor 74 in addition to the transistor 70. Each of the diodes 71 and 72 is formed by connecting the base to the collector of the corresponding npn transistor.

In the first bias circuit 7, the two diodes 71 and 72 are connected to each other in series between the ground and the base of the transistor 70. In the first bias circuit 7, the base of the transistor 70 is connected through the resistor 74 to a first constant-current source 117 included in a control circuit 110 in the radio-frequency circuit 100. In the first bias circuit 7, the capacitor 73 is connected between the ground and the base of the transistor 70.

In the first bias circuit 7, a constant current, which is output from the first constant-current source 117, is received at the base of the transistor 70. The constant current is amplified to obtain the first bias current I1 which is output from the emitter of the transistor 70. The first bias current I1, which is output from the emitter of the transistor 70, is supplied to the first input terminal 11 of the first transistor Q1 through the resistor 77. The resistor 77 may be included in the first bias circuit 7.

The second bias circuit 9 is connected to the second input terminal 31 of the second transistor Q3. The second bias circuit 9 supplies a second bias to the second transistor Q3. More specifically, the second bias circuit 9 supplies a second bias current I3 to the second input terminal 31 of the second transistor Q3.

The second bias circuit 9 includes a transistor 90. The transistor 90 has a control terminal, a first main terminal, and a second main terminal. The transistor 90 is, for example, an npn bipolar transistor. In this case, the control terminal, the first main terminal, and the second main terminal in the transistor 90 are its base, its collector, and its emitter, respectively. The transistor 90 is connected, at its collector, to the power supply terminal T3, and is connected, at its emitter, to the second input terminal 31 of the second transistor Q3. More specifically, the transistor 90 is connected, at its emitter, to the second input terminal 31 of the second transistor Q3 through a resistor 97. As described above, the power supply terminal T3 is supplied with the power supply voltage Vbat from the battery. The second bias current I3, which is output from the second bias circuit 9, is supplied to the second input terminal 31 of the second transistor Q3 through the resistor 97. The second bias current I3 is a direct current which determines the operating point of the second transistor Q3. In the second bias circuit 9, the transistor 90 is used as an emitter-follower transistor. The transistor 90 is a transistor for amplifying a current.

The second bias circuit 9 includes two diodes 91 and 92, a capacitor 93, and a resistor 94 in addition to the transistor 90. Each of the two diodes 91 and 92 is formed by connecting the base to the collector of the corresponding npn transistor.

In the second bias circuit 9, the two diodes 91 and 92 are connected to each other in series between the ground and the base of the transistor 90. In the second bias circuit 9, the base of the transistor 90 is connected through the resistor 94 to a second constant-current source 119 included in the control circuit 110. In the second bias circuit 9, the capacitor 93 is connected between the ground and the base of the transistor 90.

In the second bias circuit 9, a constant current, which is output from the second constant-current source 119, is received at the base of the transistor 90. The constant current is amplified to obtain the second bias current I3 which is output from the emitter of the transistor 90. The second bias current I3, which is output from the emitter of the transistor 90, is supplied to the second input terminal 31 of the second transistor Q3 through the resistor 97. The resistor 97 may be included in the second bias circuit 9.

The third bias circuit 8 is connected to the third input terminal 21 of the third transistor Q2. The third bias circuit 8 supplies a third bias to the third transistor Q2. More specifically, the third bias circuit 8 supplies a third bias current I2 to the third input terminal 21 of the third transistor Q2.

The third bias circuit 8 includes a transistor 80. The transistor 80 has a control terminal, a first main terminal, and a second main terminal. The transistor 80 is, for example, an npn bipolar transistor. In this case, the control terminal, the first main terminal, and the second main terminal in the transistor 80 are its base, its collector, and its emitter, respectively. The transistor 80 is connected, at its collector, to the power supply terminal T3, and is connected, at its emitter, to the third input terminal 21 of the third transistor Q2. More specifically, the transistor 80 is connected, at its emitter, to the third input terminal 21 of the third transistor Q2 through a resistor 87. As described above, the power supply terminal T3 is supplied with the power supply voltage Vbat from the battery. The third bias current I2, which is output from the third bias circuit 8, is supplied to the third input terminal 21 of the third transistor Q2 through the resistor 87. The third bias current I2 is a direct current which determines the operating point of the third transistor Q2. In the third bias circuit 8, the transistor 80 is used as an emitter-follower transistor. The transistor 80 is a transistor for amplifying a current.

The third bias circuit 8 includes two diodes 81 and 82, a capacitor 83, and a resistor 84 in addition to the transistor 80. Each of the two diodes 81 and 82 is formed by connecting the base to the collector of the corresponding npn transistor.

In the third bias circuit 8, the two diodes 81 and 82 are connected to each other in series between the ground and the base of the transistor 80. In the third bias circuit 8, the base of the transistor 80 is connected through the resistor 84 to a third constant-current source 118 included in the control circuit 110. In the third bias circuit 8, the capacitor 83 is connected between the ground and the base of the transistor 80.

In the third bias circuit 8, a constant current, which is output from the third constant-current source 118, is received at the base of the transistor 80. The constant current is amplified to obtain the third bias current I2 which is output from the emitter of the transistor 80. The third bias current I2, which is output from the emitter of the transistor 80, is supplied to the third input terminal 21 of the third transistor Q2 through the resistor 87. The resistor 87 may be included in the third bias circuit 8.

As illustrated in FIG. 1, the first matching circuit MN1 is disposed between the signal input terminal T1 and the first input terminal 11 of the first transistor Q1. The first matching circuit MN1 is a circuit for impedance matching between the first transistor Q1 and the signal processing circuit 301. The first matching circuit MN1 includes, for example, at least one of the following devices: one resistor; one capacitor; and one inductor. However, the configuration is not limited to this.

The second matching circuit MN3 is disposed between the second input terminal 31 of the second transistor Q3 and the third output terminal 22 of the third transistor Q2. The second matching circuit MN3 is a circuit (interstage matching circuit) for impedance matching between the second transistor Q3 and the third transistor Q2. The second matching circuit MN3 includes, for example, at least one of the following devices: one resistor; one capacitor; and one inductor. However, the configuration is not limited to this.

The third matching circuit MN2 is disposed between the first output terminal 12 of the first transistor Q1 and the third input terminal 21 of the third transistor Q2. The third matching circuit MN2 is a circuit (interstage matching circuit) for impedance matching between the first transistor Q1 and the third transistor Q2. The third matching circuit MN2 includes, for example, at least one of the following devices: one resistor; one capacitor; and one inductor. However, the configuration is not limited to this.

The power amplification circuit 10 further includes a first capacitor C1, a second capacitor C3, and a third capacitor C2. The first capacitor C1, the second capacitor C3, and the third capacitor C2 are capacitive elements for cutting direct current.

The first capacitor C1 is disposed between the first matching circuit MN1 and the first input terminal 11 of the first transistor Q1. The first capacitor C1 is connected, at its first end, to the first matching circuit MN1, and is connected, at its second end, to the first input terminal 11. The first bias circuit 7 is connected through the resistor 77 to a first node N1 on the path between the first capacitor C1 and the first input terminal 11. The first capacitor C1 may be included in the first matching circuit MN1.

The second capacitor C3 is disposed between the second matching circuit MN3 and the second input terminal 31 of the second transistor Q3. The second capacitor C3 is connected, at its first end, to the second matching circuit MN3, and is connected, at its second end, to the second input terminal 31. The second bias circuit 9 is connected through the resistor 97 to a second node N3 on the path between the second capacitor C3 and the second input terminal 31. The second capacitor C3 may be included in the second matching circuit MN3.

The third capacitor C2 is disposed between the third matching circuit MN2 and the third input terminal 21 of the third transistor Q2. The third capacitor C2 is connected, at its first end, to the third matching circuit MN2, and is connected, at its second end, to the third input terminal 21. The third bias circuit 8 is connected through the resistor 87 to a third node N2 on the path between the third capacitor C2 and the third input terminal 21. The third capacitor C2 may be included in the third matching circuit MN2.

The first voltage control circuit 4 applies the first power supply voltage Vcc1 (see FIG. 3) to the first transistor Q1. The first voltage control circuit 4 is, for example, a LDO (Low Dropout) regulator as illustrated in FIG. 3. The LDO regulator forming the first voltage control circuit 4 includes a transistor 40 (hereinafter referred to as a first output transistor 40), two resistors 41 and 42, an error amplifier EA1 (hereinafter referred to as a first error amplifier EA1), and a control terminal T4 (hereinafter referred to as a first control terminal T4).

The first output transistor 40 has a control terminal, a first main terminal, and a second main terminal. The first output transistor 40 is, for example, a p-channel MOSFET. In this case, the control terminal, the first main terminal, and the second main terminal in the first output transistor 40 are its gate, its drain, and its source, respectively. The first output transistor 40 is connected, at its source, to the power supply terminal T3 through the input terminal of the first voltage control circuit 4, and is connected, at its drain, to the first output terminal 12 of the first transistor Q1 through the output terminal of the first voltage control circuit 4. The on-resistance (Ron) of the first output transistor 40 can take a lower value. The first output transistor 40 is connected, at its gate, to the output terminal of the first error amplifier EA1. The first output transistor 40 is not limited to a p-channel MOSFET, and may be, for example, an n-channel MOSFET, a pnp bipolar transistor, or an npn bipolar transistor.

A resistor divider circuit (hereinafter referred to as a first resistor divider circuit) including a series circuit of the two resistors 41 and 42 is connected between the ground and the drain of the first output transistor 40.

The first error amplifier EA1 is connected, at its inverting input terminal, to the first control terminal T4. The first error amplifier EA1 is connected, at its non-inverting input terminal, to a node between the two resistors 41 and 42 in the first resistor divider circuit. The first error amplifier EA1 is connected, at its output terminal, to the gate of the first output transistor 40.

The first error amplifier EA1 compares the potential, which is received at its inverting input terminal, with the potential, which is received at its non-inverting input terminal, and amplifies an error signal which indicates the difference. For example, the inverting input terminal receives the control voltage Vramp from the signal processing circuit 301 through the first control terminal T4. The resistance value of the resistor 41 is represented by R41, and the resistance value of the resistor 42 is represented by R42. The relationship between the control voltage Vramp and the first power supply voltage Vcc1, which is output from the first voltage control circuit 4, may be expressed as Vcc1=Vramp×(1+R41/R42).

The second voltage control circuit 5 applies the second power supply voltage Vcc2 (see FIG. 4) to the second transistor Q3. The second voltage control circuit 5 is, for example, an LDO regulator as illustrated in FIG. 4. The LDO regulator forming the second voltage control circuit 5 includes a transistor 50 (hereinafter referred to as a second output transistor 50), two resistors 51 and 52, an error amplifier EA2 (hereinafter referred to as a second error amplifier EA2), and a control terminal T5 (hereinafter referred to as a second control terminal T5). The second output transistor 50 has a control terminal, a first main terminal, and a second main terminal.

The second output transistor 50 has a control terminal, a first main terminal, and a second main terminal. The second output transistor 50 is, for example, a p-channel MOSFET. In this case, the control terminal, the first main terminal, and the second main terminal in the second output transistor 50 are its gate, its drain, and its source, respectively. The second output transistor 50 is connected, at its source, to the power supply terminal T3 through the input terminal of the second voltage control circuit 5, and is connected, at its drain, to the second output terminal 32 of the second transistor Q3 through the output terminal of the second voltage control circuit 5. The on-resistance of the second output transistor 50 can take a lower value. The second output transistor 50 is connected, at its gate, to the output terminal of the second error amplifier EA2. The second output transistor 50 is not limited to a p-channel MOSFET, and may be, for example, an n-channel MOSFET, a pnp bipolar transistor, or an npn bipolar transistor.

A resistor divider circuit (hereinafter referred to as a second resistor divider circuit) including a series circuit of the two resistors 51 and 52 is connected between the ground and the drain of the second output transistor 50.

The second error amplifier EA2 is connected, at its inverting input terminal, to the second control terminal T5. The second error amplifier EA2 is connected, at its non-inverting input terminal, to a node between the two resistors 51 and 52 in the second resistor divider circuit. The second error amplifier EA2 is connected, at its output terminal, to the gate of the second output transistor 50.

The second error amplifier EA2 compares the potential, which is received at its inverting input terminal, with the potential, which is received at its non-inverting input terminal, and amplifies an error signal which indicates the difference. The inverting input terminal receives, for example, the control voltage Vramp from the signal processing circuit 301 through the second control terminal T5. The resistance value of the resistor 51 is represented by R51, and the resistance value of the resistor 52 is represented by R52. The relationship between the control voltage Vramp and the second power supply voltage Vcc2, which is output from the second voltage control circuit 5, may be expressed as Vcc2=Vramp×(1+R51/R52).

The third voltage control circuit 6 is, for example, an LDO regulator. The circuit configuration of the LDO regulator forming the third voltage control circuit 6 is substantially the same as that of the first voltage control circuit 4, and will be neither described nor illustrated.

In the second voltage control circuit 5, for example, when R51/R52=1, if the control voltage Vramp is 0.5 V, the second control voltage Vcc2 is 1 V. In the second voltage control circuit 5, for example, when R51/R52= 1/100, if the control voltage Vramp is 0.5 V, the second control voltage Vcc2 is 0.505 V. In the power amplification circuit 10 according to the first embodiment, the value of R51/R52 for the second voltage control circuit 5 is different from the value of R41/R42 for the first voltage control circuit 4. Thus, the power amplification circuit 10 according to the first embodiment may control the first power supply voltage Vcc1 and the second power supply voltage Vcc2 independently, enabling the value of the first power supply voltage Vcc1 to be different from that of the second power supply voltage Vcc2. In the power amplification circuit 10 according to the first embodiment, the time, at which the second voltage control circuit 5 starts applying the second power supply voltage Vcc2 to the second transistor Q3, is later than the time, at which the first voltage control circuit 4 starts applying the first power supply voltage Vcc1 to the first transistor Q1. In the power amplification circuit 10, for example, the value of R41/R42 is made different from the value of R51/R52 appropriately. This enables the time, at which the second output transistor 50 is switched from the off state to the on state, to be delayed with respect to the time, at which the first output transistor 40 is switched from the off state to the on state. Therefore, the power amplification circuit 10 enables the time, at which the second voltage control circuit 5 starts applying the second power supply voltage Vcc2 to the second transistor Q3, to be later than (to be delayed with respect to) the time, at which the first voltage control circuit 4 starts applying the first power supply voltage Vcc1 to the first transistor Q1. In the power amplification circuit 10, the value of R41/R42 is three, and the value of R51/R52 is one. However, these values are exemplary, and are not particularly limited.

In the power amplification circuit 10, at the point at which the second transistor Q3 starts operating, the first power supply voltage Vcc1 applied to the first transistor Q1 by the first voltage control circuit 4 is a voltage higher than the knee voltage of the first transistor Q1. The knee voltage of the first transistor Q1 is a collector voltage at which the static characteristics of the first transistor Q1 are shifted from the linear region to the saturation region. In the first transistor Q1, the conductance in the saturation region is less than that in the linear region. The conductance indicates a rate of change of the collector current with respect to the change of the collector voltage of the first transistor Q1. The conductance in the saturation region can be small. The knee voltage of the first transistor Q1 depends on the value of the first bias current I1. In the circuit design of the power amplification circuit 10, for example, the value of R51/R52 is determined so that the second transistor Q3 starts operating at a control voltage Vramp which is higher than that at which the first power supply voltage Vcc1 of the first transistor Q1 reaches the knee voltage.

### (2) Operations of the Power Amplification Circuit, the Control Circuit, and the Communication Device

In the power amplification circuit 10, the power supply voltage Vbat is supplied from the battery through the power supply terminal T3 to the first voltage control circuit 4, the second voltage control circuit 5, and the third voltage control circuit 6. In the power amplification circuit 10, the power supply voltage Vbat is also supplied to the first bias circuit 7, the second bias circuit 9, and the third bias circuit 8.

For example, the power amplification circuit 10 amplifies, for output, a radio-frequency signal (transmit signal) from the signal processing circuit 301. The power amplification circuit 10 amplifies a radio-frequency signal received at the signal input terminal T1, and outputs the amplified radio-frequency signal from the signal output terminal T2. In the power amplification circuit 10, each of the first transistor Q1, the third transistor Q2, and the second transistor Q3 amplifies, for output, a received radio-frequency signal.

The power amplification circuit 10 is controlled by the signal processing circuit 301 and the control circuit 110. The control circuit 110 is, for example, a control IC (Integrated Circuit) which controls the power amplification circuit 10. The control circuit 110 controls the first bias circuit 7, the second bias circuit 9, and the third bias circuit 8. As described above, the control circuit 110 is not a component of the power amplification circuit 10, and is a component of the radio-frequency circuit 100. The control circuit 110 includes the first constant-current source 117, the second constant-current source 119, and the third constant-current source 118 which are described above.

The control circuit 110 controls the power amplification circuit 10 on the basis of a control signal obtained from the signal processing circuit 301. The control circuit 110 controls the power amplification circuit 10 in accordance with a control signal from the RF-signal processing circuit 302 of the signal processing circuit 301. For example, the control circuit 110 may store, in advance, the relationship between the value of the output power (transmit power) of the power amplification circuit 10 and the value of the control voltage Vramp in a Look up table or the like. In this case, when the control circuit 110 receives, from the signal processing circuit 301, an instruction about the value of the transmit power which is required for the power amplification circuit 10, the control circuit 110 may refer to the Look up table to control the value of the control voltage Vramp in accordance with the requested value of the transmit power. Any configuration may be employed as long as, for example, the control circuit 110 controls the power amplification circuit 10 in accordance with a digital control signal from the RF-signal processing circuit 302 of the signal processing circuit 301.

When the control circuit 110 causes the power amplification circuit 10 to operate, for example, the control circuit 110 causes the first bias circuit 7, the second bias circuit 9, and the third bias circuit 8 to be supplied with constant currents from the first constant-current source 117, the second constant-current source 119, and the third constant-current source 118, respectively.

In the power amplification circuit 10, the control voltage Vramp from the signal processing circuit 301 is provided to the first voltage control circuit 4, the second voltage control circuit 5, and the third voltage control circuit 6.

In the power amplification circuit 10, each of the first transistor Q1, the third transistor Q2, and the second transistor Q3 amplifies, for output, a received radio-frequency signal.

### (3) Characteristics of the Power Amplification Circuit

FIG. 6 is a characteristics diagram, of the power amplification circuit 10, which illustrates the relationship between the control voltage Vramp and idle currents, that is, a first idle current Idle1 of the first transistor Q1, a second idle current Idle3 of the second transistor Q3, and a third idle current Idle2 of the third transistor Q2. In FIG. 6, the horizontal axis represents the control voltage Vramp. In FIG. 6, the vertical axis on the left represents the idle current Idle3 of the second transistor Q3. The idle current Idle3 of the second transistor Q3 is a collector-emitter current of the second transistor Q3 obtained with supply of the second bias current I3 to the second transistor Q3. In FIG. 6, the vertical axis on the right represents the idle current Idle1 of the first transistor Q1 and the idle current Idle2 of the third transistor Q2. The idle current Idle1 of the first transistor Q1 is a collector-emitter current of the first transistor Q1 obtained with supply of the first bias current I1 to the first transistor Q1. The idle current Idle2 of the third transistor Q2 is a collector-emitter current of the third transistor Q2 obtained with supply of the third bias current I2 to the third transistor Q2. In FIG. 6, the solid line denoted as “1st” corresponds to the idle current Idle1 of the first transistor Q1; the solid line denoted as “2nd” corresponds to the idle current Idle2 of the third transistor Q2; the solid line denoted as “3rd” corresponds to the idle current Idle3 of the second transistor Q3.

FIG. 6 shows that, in the power amplification circuit 10, the time, at which the idle current Idle3 of the second transistor Q3 starts flowing, is delayed with respect to the time, at which the idle current Idle1 of the first transistor Q1 starts flowing, and the time, at which the idle current Idle2 of the third transistor Q2 starts flowing. In addition, FIG. 6 shows that, in the power amplification circuit 10, the idle current Idle3 of the second transistor Q3 is larger than the idle current Idle1 of the first transistor Q1 and the idle current Idle2 of the third transistor Q2.

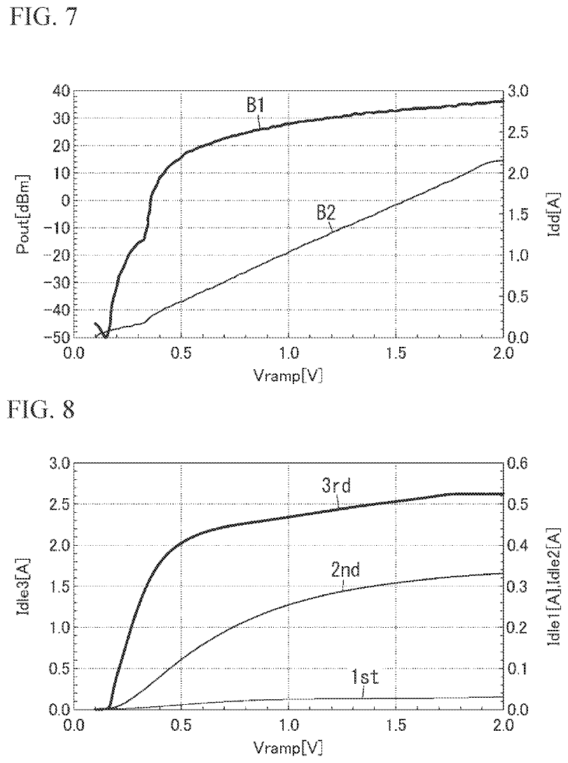

FIG. 7 is a characteristics diagram, of the power amplification circuit 10, which illustrates the relationship between the control voltage Vramp and the output power Pout and the relationship between the control voltage Vramp and collector current Idd of the second transistor Q3. In FIG. 7, the horizontal axis represents the control voltage Vramp. In FIG. 7, the vertical axis on the left represents the output power Pout of the power amplification circuit 10. In FIG. 7, the vertical axis on the right represents the collector current Idd of the second transistor Q3. In FIG. 7, the solid line denoted as “B1” corresponds to the output power Pout of the power amplification circuit 10; the solid line denoted as “B2” corresponds to the collector current Idd of the second transistor Q3.

FIG. 7 shows that, in the power amplification circuit 10, as the control voltage Vramp increases from 0.15 V to 2 V, the output power Pout increases. In the power amplification circuit 10, after the first transistor Q1 is saturated, the second transistor Q3 starts operating. Thus, the relationship between the control voltage Vramp and the output power Pout is illustrated as B1 in FIG. 7. The output power Pout obtained when the second transistor Q3 does not operate is power which leaks through isolation of the second transistor Q3 receiving the output of the first transistor Q1 through the third transistor Q2.

In addition, FIG. 7 shows that the power amplification circuit 10 has substantially linear characteristics between the output power Pout and the collector current Idd.

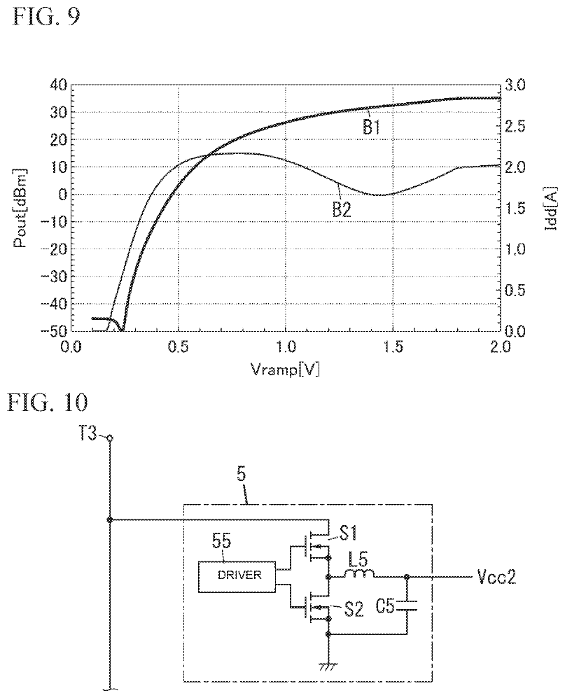

Characteristics of a power amplification circuit according to a comparison example of the power amplification circuit 10 according to the first embodiment will be described on the basis of FIGS. 8 and 9. The power amplification circuit according to the comparison example is not illustrated. The power amplification circuit according to the comparison example will be described by designating, with the same reference numbers, substantially the same components as those of the power amplification circuit 10 according to the first embodiment. A power control circuit according to the comparison example is different from the power amplification circuit 10 according to the first embodiment in that the power control circuit according to the comparison example includes a single voltage control circuit instead of the first voltage control circuit 4, the second voltage control circuit 5, and the third voltage control circuit 6 of the power amplification circuit 10 according to the first embodiment, and in that the voltage control circuit is connected to the first transistor Q1, the second transistor Q3, and the third transistor Q2. Reading of FIGS. 8 and 9 is the same as that of FIGS. 6 and 7, respectively.

As shown in FIG. 8, in the power amplification circuit according to the comparison example, the time, at which the idle current Idle1 of the first transistor Q1 starts flowing, the time, at which the idle current Idle3 of the second transistor Q3 starts flowing, and the time, at which the idle current Idle2 of the third transistor Q2 starts flowing, are substantially the same.

As shown in FIGS. 7 and 9, in a range in which Vramp is relatively low, the collector current Idd of the second transistor Q3 in the power amplification circuit according to the comparison example is larger than the collector current Idd of the second transistor Q3 of the power amplification circuit 10 according to the first embodiment. This is because the operating region of the second transistor Q3 has not shifted to the saturation region.

FIGS. 7 and 9 show that, when the output power Pout is relatively low, the power amplification circuit 10 according to the first embodiment enables the collector current Idd of the second transistor Q3 to be made smaller than that of the power amplification circuit according to the comparison example.

### (4) A Radio-Frequency Module Having the Radio-Frequency Circuit

A radio-frequency module includes a mount board, multiple electronic components mounted on the mount board, and multiple external connection terminals disposed on the mount board. The electronic components include multiple components forming the power amplification circuit 10, one or more components forming the output matching circuit 101, a component forming the first switch 102, a component forming the filter 103, and a component forming the second switch 104. The external connection terminals include the antenna terminal 105, the radio-frequency signal input terminal 106, the terminal-for-power-supply 111, and the ground terminal.

The components forming the power amplification circuit 10 are, for example, a first IC chip, a second IC chip, a third IC chip, a fourth IC chip, and a fifth IC chip. The first IC chip is, for example, a GaAs-based IC chip including the first transistor Q1, the second transistor Q3, and the third transistor Q2. In this case, the bipolar transistor included in each of the first transistor Q1, the second transistor Q3, and the third transistor Q2 is for example, a HBT (Heterojunction Bipolar Transistor). The first IC chip also includes the first bias circuit 7, the second bias circuit 9, and the third bias circuit 8. The first IC chip is not limited to a GaAs-based IC chip, and may be, for example, an Si-based IC chip, an SiGe-based IC chip, or a GaN-based IC chip.

The second IC chip includes the first voltage control circuit 4. The third IC chip includes the second voltage control circuit 5. The fourth IC chip includes the third voltage control circuit 6.

A component forming the control circuit 110 is, for example, the fifth IC chip. The fifth IC chip includes the control circuit 110. The fifth IC chip is, for example, an Si-based IC chip. The control circuit 110 is, for example, a MOS IC (Metal Oxide Semiconductor Integrated Circuit) including multiple MOSFETs.

### (5) Conclusion

### (5.1) The Power Amplification Circuit

The power amplification circuit 10 according to the first embodiment power-amplifies a radio-frequency signal. The power amplification circuit 10 includes the driving-stage amplifier 1, the final-stage amplifier 3, the power supply terminal T3, the first voltage control circuit 4, and the second voltage control circuit 5. The driving-stage amplifier 1 includes the first transistor Q1. The first transistor Q1 has the first input terminal 11, the first output terminal 12, and the first ground terminal 13. The final-stage amplifier 3 includes the second transistor Q3. The second transistor Q3 has the second input terminal 31, the second output terminal 32, and the second ground terminal 33. The second input terminal 31 is connected to the first output terminal 12. The first voltage control circuit 4 is connected between the power supply terminal T3 and the first output terminal 12. The first voltage control circuit 4 controls the first power supply voltage Vcc1 applied to the first transistor Q1. The second voltage control circuit 5, which is a circuit different from the first voltage control circuit 4, is connected between the power supply terminal T3 and the second output terminal 32. The second voltage control circuit 5 controls the second power supply voltage Vcc2 applied to the second transistor Q3.

The power amplification circuit 10 according to the first embodiment enables suppression of the current (collector current Idd) flowing through the second transistor Q3 of the final-stage amplifier 3. The power amplification circuit 10 according to the first embodiment may increase the input power of the second transistor Q3 when the second power supply voltage Vcc2 to the second transistor Q3 is relatively low, and may increase efficiency of the second transistor Q3, enabling suppression of the current (collector current Idd) flowing through the second transistor Q3 in operation with relatively low output power Pout (in low power).

The power amplification circuit 10 according to the first embodiment includes the first voltage control circuit 4, the second voltage control circuit 5, and the third voltage control circuit 6 which are different from each other. Thus, the power amplification circuit 10 according to the first embodiment enables isolation to be improved because the power supply terminal T3 is connected directly to none of the first transistor Q1, the second transistor Q3, and the third transistor Q2.

The power amplification circuit 10 according to the first embodiment enables suppression of change of the load capacitance at the base of each of the first transistor Q1, the second transistor Q3, and the third transistor Q2 in such a manner that the value of the first bias current I1, that of the second bias current I3, and that of the third bias current I2 are made constant. This enables the power amplification circuit 10 to obtain an open-loop frequency response.

### (5.2) The Radio-Frequency Circuit

The radio-frequency circuit 100 according to the first embodiment includes the power amplification circuit 10 and the filter 103. The filter 103 passes a radio-frequency signal, which is power-amplified by the power amplification circuit 10 and is output from the power amplification circuit 10.

The radio-frequency circuit 100 according to the first embodiment, which includes the power amplification circuit 10, enables suppression of the current flowing through the second transistor Q3 of the final-stage amplifier 3 of the power amplification circuit 10.

### (5.3) Communication Device

The communication device 300 according to the first embodiment includes the radio-frequency circuit 100 and the signal processing circuit 301. The signal processing circuit 301 outputs a radio-frequency signal to the radio-frequency circuit 100.

The communication device 300 according to the first embodiment, which includes the radio-frequency circuit 100 having the power amplification circuit 10, enables suppression of the current flowing through the second transistor Q3 of the final-stage amplifier 3 of the power amplification circuit 10.

### Modified Examples of the First Embodiment

The second voltage control circuit 5 is not limited to an LDO regulator as illustrated in FIG. 4, and may be, for example, a DC-DC converter. Such a DC-DC converter is a switching regulator. FIG. 10 illustrates an exemplary DC-DC converter forming the second voltage control circuit 5. The DC-DC converter illustrated in FIG. 10 is a step-down DC-DC converter including a series circuit of two switching elements (field-effect transistors) S1 and S2, a series circuit of an inductor L5 and a capacitor C5, and a driver 55. In the DC-DC converter, the series circuit of the inductor L5 and the capacitor C5 is connected to the switching element Q2 in parallel. Each of the two switching elements S1 and S2 is, for example, an n-channel MOSFET, and includes a parasitic diode.

In the DC-DC converter illustrated in FIG. 10, the driver 55 drives the two switching elements S1 and S2. The driver 55 is controlled by the signal processing circuit 301 or the control circuit 110. Thus, the power amplification circuit 10 enables the time, at which the second power supply voltage Vcc2 is applied to the second transistor Q3, to be delayed with respect to the time, at which the first power supply voltage Vcc1 is applied to the first transistor Q1.

The first voltage control circuit 4 may have any configuration as long as the first voltage control circuit 4 is a regulator. The first voltage control circuit 4 is not limited to an LDO regulator as illustrated in FIG. 3, and may be, for example, a DC-DC converter having a circuit configuration substantially the same as that in FIG. 10.

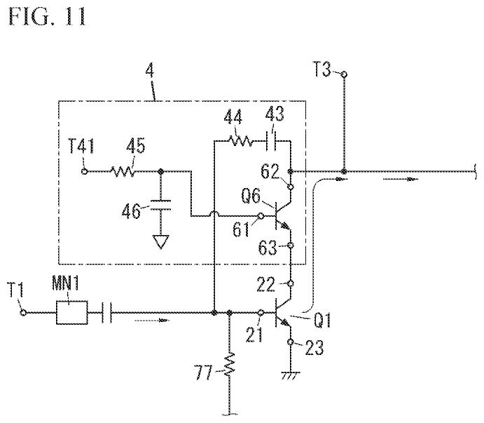

Alternatively, as illustrated in FIG. 11, for example, the first voltage control circuit 4 may be a circuit including a transistor Q6 cascode-connected to the first transistor Q1. The arrows in FIG. 11 are illustrated for describing the path through which a radio-frequency signal passes.

The transistor Q6 has a base terminal 61, a collector terminal 62, and an emitter terminal 63. The transistor Q6 is connected, at the emitter terminal 63, to the first output terminal 12 of the first transistor Q1. At the base terminal 61, the transistor Q6 is connected to the ground through a capacitor 46, and is also connected to a bias terminal T41 through a resistor 45. At the collector terminal 62, the transistor Q6 is connected to the power supply terminal T3, and is also connected to the first input terminal 11 of the first transistor Q1 through a series circuit of a capacitor 43 and a resistor R44. The bias terminal T41 is connected to the control circuit 110, and is provided with a bias from the control circuit 110.

### Second Embodiment

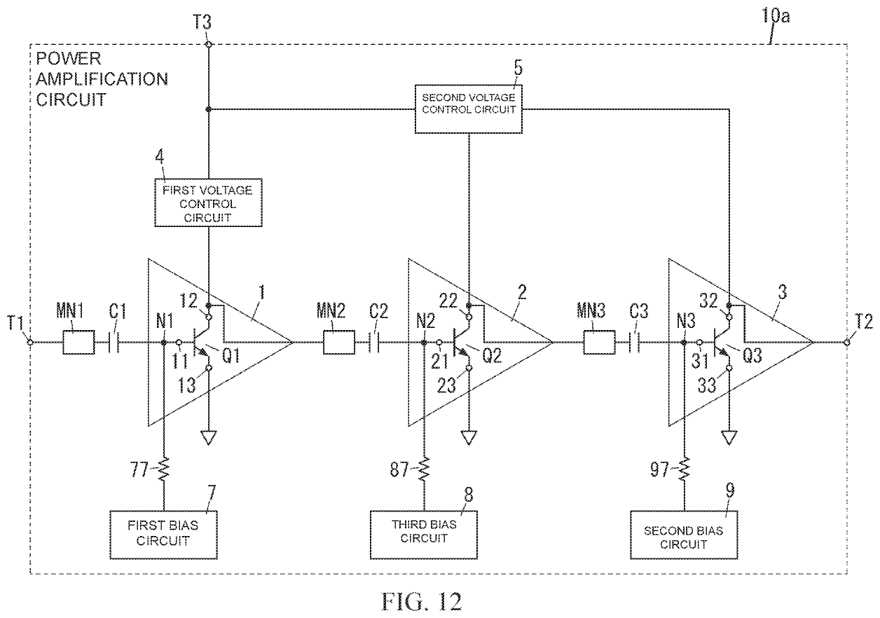

A power amplification circuit 10a according to a second embodiment will be described below by referring to FIG. 12. Components of the power amplification circuit 10a according to the second embodiment, which are substantially the same as those in the power amplification circuit 10 according to the first embodiment, are designated with the same reference numerals, and will not be described. The power amplification circuit 10a according to the second embodiment may be used instead of the power amplification circuit 10 in the radio-frequency circuit 100 (see FIG. 2) and the communication device 300 (see FIG. 2) according to the first embodiment. In other words, the radio-frequency circuit 100 and the communication device 300 may include the power amplification circuit 10a according to the second embodiment instead of the power amplification circuit 10 according to the first embodiment.

The power amplification circuit 10a according to the second embodiment does not include the third voltage control circuit 6 of the power amplification circuit 10 according to the first embodiment. In the power amplification circuit 10a according to the second embodiment, the second voltage control circuit 5 is connected to the second transistor Q3 and the third transistor Q2. In the power amplification circuit 10a according to the second embodiment, the second power supply voltage Vcc2 is applied to the second transistor Q3 and the third transistor Q2.

Like the power amplification circuit 10 according to the first embodiment, the power amplification circuit 10a according to the second embodiment includes the first voltage control circuit 4, which applies the first power supply voltage Vcc1 to the first transistor Q1, and the second voltage control circuit 5, which applies the second power supply voltage Vcc2 to the second transistor Q3. Thus, like the power amplification circuit 10 according to the first embodiment, the power amplification circuit 10a according to the second embodiment enables suppression of the current flowing through the second transistor Q3 of the final-stage amplifier 3.

### Third Embodiment

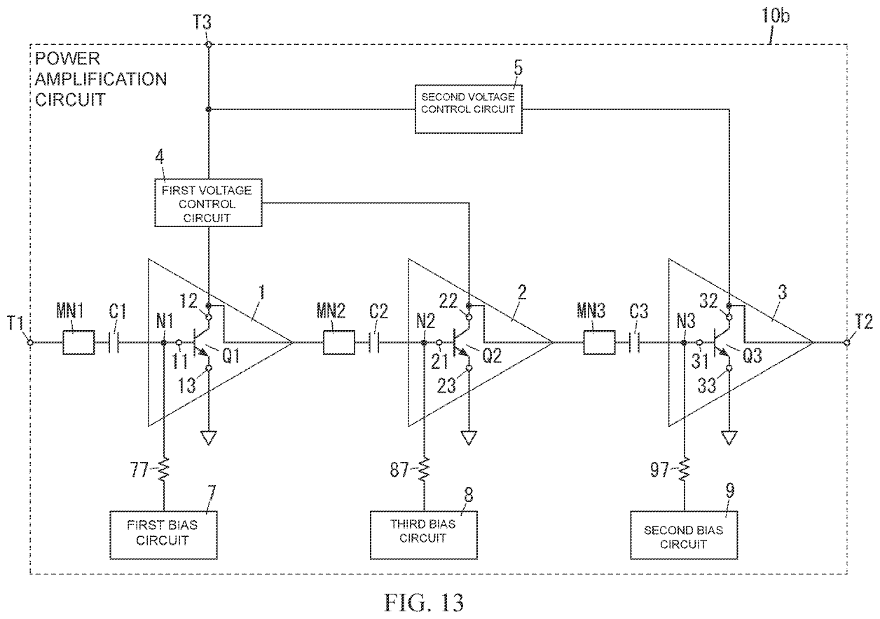

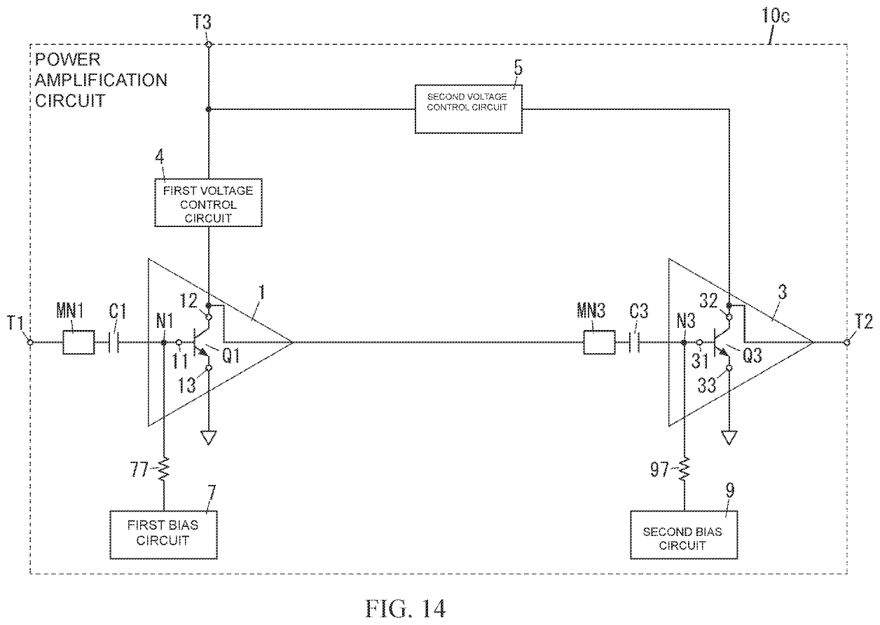

A power amplification circuit 10b according to a third embodiment will be described below by referring to FIG. 13. Components of the power amplification circuit 10b according to the third embodiment, which are substantially the same as those of the power amplification circuit 10 according to the first embodiment, are designated with the same reference numbers, and will not be described. The power amplification circuit 10b according to the third embodiment may be used instead of the power amplification circuit 10 in the radio-frequency circuit 100 (see FIG. 2) and the communication device 300 (see FIG. 2) according to the first embodiment. In other words, the radio-frequency circuit 100 and the communication device 300 may include the power amplification circuit 10b according to the third embodiment instead of the power amplification circuit 10 according to the first embodiment.

The power amplification circuit 10b according to the third embodiment does not include the third voltage control circuit 6 of the power amplification circuit 10 according to the first embodiment. In the power amplification circuit 10b according to the third embodiment, the first voltage control circuit 4 is connected to the first transistor Q1 and the third transistor Q2. In the power amplification circuit 10b according to the third embodiment, the first power supply voltage Vcc1 is applied to the first transistor Q1 and the third transistor Q2.

Like the power amplification circuit 10 according to the first embodiment, the power amplification circuit 10b according to the third embodiment includes the first voltage control circuit 4, which applies the first power supply voltage Vcc1 to the first transistor Q1, and the second voltage control circuit 5, which applies the second power supply voltage Vcc2 to the second transistor Q3. Thus, like the power amplification circuit 10 according to the first embodiment, the power amplification circuit 10b according to the third embodiment enables suppression of the current flowing through the second transistor Q3 of the final-stage amplifier 3.

### Fourth Embodiment

A power amplification circuit 10c according to a fourth embodiment will be described below by referring to FIG. 14. Components of the power amplification circuit 10c according to the fourth embodiment, which are substantially the same as those of the power amplification circuit 10 according to the first embodiment, are designated with the same reference numbers, and will not be described. The power amplification circuit 10c according to the fourth embodiment may be used instead of the power amplification circuit 10 in the radio-frequency circuit 100 (see FIG. 2) and the communication device 300 (see FIG. 2) according to the first embodiment. In other words, the radio-frequency circuit 100 and the communication device 300 may include the power amplification circuit 10c according to the fourth embodiment instead of the power amplification circuit 10 according to the first embodiment.

The power amplification circuit 10c according to the fourth embodiment does not include the interstage amplifier 2, the third matching circuit NM2, the third capacitor C2, and the third voltage control circuit 6 which are included in the power amplification circuit 10 according to the first embodiment.

In the power amplification circuit 10c according to the fourth embodiment, the second matching circuit MN3 is disposed between the second input terminal 31 of the second transistor Q3 and the first output terminal 12 of the first transistor Q1. The second matching circuit MN3 is a circuit (interstage matching circuit) for impedance matching between the second transistor Q3 and the first transistor Q1.

Like the power amplification circuit 10 according to the first embodiment, the power amplification circuit 10c according to the fourth embodiment includes the first voltage control circuit 4, which applies the first power supply voltage Vcc1 to the first transistor Q1, and the second voltage control circuit 5, which applies the second power supply voltage Vcc2 to the second transistor Q3. Thus, like the power amplification circuit 10 according to the first embodiment, the power amplification circuit 10c according to the fourth embodiment enables suppression of the current flowing through the second transistor Q3 of the final-stage amplifier 3.

### MODIFIED EXAMPLES

The first to fourth embodiments and the like are merely one of various embodiments of the present disclosure. The first to fourth embodiments and the like may be changed variously, for example, in accordance with the design as long as the object of the present disclosure is achieved.

For example, the number of stages of each of the power amplification circuits 10, 10a, and 10b is not limited to three, and may be four or more. That is, each of the power amplification circuits 10, 10a, and 10b may include two or more interstage amplifiers 2 between the driving-stage amplifier 1 and the final-stage amplifier 3.

In the power amplification circuit 10, each of the first transistor Q1, the second transistor Q3, and the third transistor Q2 is a bipolar transistor. The configuration is not limited to this. For example, each of the first transistor Q1, the second transistor Q3, and the third transistor Q2 may be an FET (Field Effect Transistor). Such a FET is, for example, a MOSFET (Metal-Oxide-Semiconductor Field Effect Transistor). When the first transistor Q1 is a MOSFET, the first input terminal 11, the first output terminal 12, and the first ground terminal 13 are, for example, its gate terminal, its drain terminal, and its source terminal. The first bias supplied from the first bias circuit 7 to the first input terminal 11 of the first transistor Q1 is a first bias voltage. When the second transistor Q3 is a MOSFET, the second input terminal 31, the second output terminal 32, and the second ground terminal 33 are, for example, its gate terminal, its drain terminal, and its source terminal. The second bias supplied from the second bias circuit 9 to the second input terminal 31 of the second transistor Q3 is a second bias voltage. When the third transistor Q2 is a MOSFET, the third input terminal 21, the third output terminal 22, and the third ground terminal 23 are, for example, its gate terminal, its drain terminal, and its source terminal. The third bias supplied from the third bias circuit 8 to the third input terminal 21 of the third transistor Q2 is a third bias voltage.

In the radio-frequency circuit 100, when the first transistor Q1, the second transistor Q3, and the third transistor Q2 of the power amplification circuit 10 are MOSFETs, not HBTs, the power amplification circuit 10 and the control circuit 110 may be integrated into a single chip.

In the radio-frequency circuit 100, the filter 103 is an acoustic wave filter using surface acoustic waves. The configuration is not limited to this. For example, an acoustic wave filter using boundary acoustic waves, plate waves, or the like may be used.

In the acoustic wave filter, each of the serial arm resonators and the parallel arm resonators is not limited to a SAW resonator, and may be, for example, a BAW (Bulk Acoustic Wave) resonator.

The radio-frequency circuit 100 may include a receive circuit having a low-noise amplifier, which amplifies receive signals received from the antenna terminal 105, and a filter connected to the low-noise amplifier.

The filter 103 is not limited to a transmit filter, and may be a duplexer.

In the radio-frequency circuit 100, the first switch 102 and the second switch 104 may be, for example, switch ICs compatible with a GPIO (General Purpose Input/Output).

### Aspects

Aspects described below are disclosed in the present specification.

A power amplification circuit (10; 10a; 10b; 10c) according to a first aspect power-amplifies a radio-frequency signal. The power amplification circuit (10; 10a; 10b; 10c) includes a driving-stage amplifier (1), a final-stage amplifier (3), a power supply terminal (T3), a first voltage control circuit (4), and a second voltage control circuit (5). The driving-stage amplifier (1) includes a first transistor (Q1). The first transistor (Q1) has a first input terminal (11), a first output terminal (12), and a first ground terminal (13). The final-stage amplifier (3) includes a second transistor (Q3). The second transistor (Q3) has a second input terminal (31), a second output terminal (32), and a second ground terminal (33). The second input terminal (31) is connected to the first output terminal (12). The first voltage control circuit (4) is connected between the power supply terminal (T3) and the first output terminal (12). The first voltage control circuit (4) controls a first power supply voltage (Vcc1) applied to the first transistor (Q1). The second voltage control circuit (5) is a circuit different from the first voltage control circuit (4), and is connected between the power supply terminal (T3) and the second output terminal (32). The second voltage control circuit (5) controls a second power supply voltage (Vcc2) applied to the second transistor (Q3).

The power amplification circuit (10; 10a; 10b; 10c) according to the first aspect enables suppression of the current (collector current Idd) flowing through the second transistor (Q3) of the final-stage amplifier (3).

According to a second aspect, in the power amplification circuit (10; 10a; 10b; 10c) according to the first aspect, control of the first power supply voltage (Vcc1) by the first voltage control circuit (4) is independent of control of the second power supply voltage (Vcc2) by the second voltage control circuit (5).

The power amplification circuit (10; 10a; 10b; 10c) according to the second aspect enables the isolation to be improved.

According to a third aspect, in the power amplification circuit (10; 10a; 10b; 10c) according to the first or second aspect, the time, at which the second voltage control circuit (5) starts applying the second power supply voltage (Vcc2) to the second transistor (Q3), is later than the time, at which the first voltage control circuit (4) starts applying the first power supply voltage (Vcc1) to the first transistor (Q1).

The power amplification circuit (10; 10a; 10b; 10c) according to the third aspect enables suppression of the current (collector current Idd) flowing through the second transistor (Q3) of the final-stage amplifier (3).

According to a fourth aspect, in the power amplification circuit (10; 10a; 10b; 10c) according to any one of the first to third aspects, at the starting point of an operation of the second transistor (Q3), the first power supply voltage (Vcc1) applied to the first transistor (Q1) by the first voltage control circuit (4) is larger than the knee voltage of the first transistor (Q1).

The power amplification circuit (10; 10a; 10b; 10c) according to the fourth aspect enables suppression of the current (collector current Idd) flowing through the second transistor (Q3) of the final-stage amplifier (3) because the first transistor (Q1) is saturated at the starting point of an operation of the second transistor (Q3).

According to a fifth aspect, in the power amplification circuit (10; 10a; 10b; 10c) according to any one of the first to fourth aspects, the first voltage control circuit (4) is a regulator.

The power amplification circuit (10; 10a; 10b; 10c) according to the fifth aspect enables the first power supply voltage (Vcc1), which is applied from the first voltage control circuit (4) to the first transistor (Q1), to be stabilized.

According to a sixth aspect, in the power amplification circuit (10; 10a; 10b; 10c) according to any one of the first to fifth aspects, the second voltage control circuit (5) is an LDO regulator.

The power amplification circuit (10; 10a; 10b; 10c) according to the sixth aspect enables suppression of occurrence of noise.

According to a seventh aspect, in the power amplification circuit (10; 10a; 10b; 10c) according to any one of the first to fifth aspects, the second voltage control circuit (5) is a DC-DC converter.

According to an eighth aspect, the power amplification circuit (10; 10a; 10b; 10c) according to any one of the first to seventh aspects further includes a first bias circuit (7) and a second bias circuit (9). The first bias circuit (7) is connected to the first input terminal (11). The second bias circuit (9) is connected to the second input terminal (31).

The power amplification circuit (10; 10a; 10b; 10c) according to the eighth aspect enables the bias (first bias current II) for the first transistor (Q1) to be controlled independently of the bias (second bias current I3) for the second transistor (Q3).

A radio-frequency circuit (100) according to a ninth aspect includes the power amplification circuit (10; 10a; 10b; 10c) according to any one of the first to eighth aspects, and a filter (103). The filter (103) passes a radio-frequency signal which is power-amplified by the power amplification circuit (10; 10a; 10b; 10c) and which is output from the power amplification circuit (10; 10a; 10b; 10c).

The radio-frequency circuit (100) according to the ninth aspect enables suppression of the current flowing through the second transistor (Q3) of the final-stage amplifier (3) of the power amplification circuit (10; 10a; 10b; 10c).

A communication device (300) according to a tenth aspect includes the radio-frequency circuit (100) according to the ninth aspect, and a signal processing circuit (301). The signal processing circuit (301) outputs a radio-frequency signal to the radio-frequency circuit (100).

The communication device (300) according to the tenth aspect enables suppression of the current flowing through the second transistor (Q3) of the final-stage amplifier (3) of the power amplification circuit (10; 10a; 10b; 10c).

### REFERENCE SIGNS LIST

1 driving-stage amplifier

2 interstage amplifier

3 final-stage amplifier

4 first voltage control circuit

40 transistor (first output transistor)

41, 42 resistor

5 second voltage control circuit

50 transistor (second output transistor)

51, 52 resistor

55 driver

6 third voltage control circuit

7 first bias circuit

8 third bias circuit

9 second bias circuit

10, 10a, 10b, 10c power amplification circuit

11 first input terminal

12 first output terminal

13 first ground terminal

21 third input terminal

22 third output terminal

23 third ground terminal

31 second input terminal

32 second output terminal

33 second ground terminal

61 base terminal

62 collector terminal

63 emitter terminal

70 transistor

71 diode

72 diode

73 capacitor

74 resistor

77 resistor

80 transistor

81 diode

82 diode

83 capacitor

84 resistor

87 resistor

90 transistor

91 diode

92 diode

93 capacitor

94 resistor

97 resistor

100 radio-frequency circuit

101 output matching circuit

102 first switch

103 filter

104 second switch

105 antenna terminal

110 control circuit

111 terminal-for-power-supply

117 first constant-current source

118 third constant-current source

119 second constant-current source

300 communication device

301 signal processing circuit

302 RF-signal processing circuit

303 baseband-signal processing circuit

310 antenna

C1 first capacitor

C2 third capacitor

C3 second capacitor

C5 capacitor

EA1 error amplifier (first error amplifier)

EA2 error amplifier (second error amplifier)

I1 first bias current

I2 third bias current

I3 second bias current

Idd collector current

Idle1 first idle current

Idle2 third idle current

Idle3 second idle current

L5 inductor

MN1 first matching circuit

MN2 third matching circuit

MN3 second matching circuit

N1 first node

N2 third node

N3 second node

Q1 first transistor

Q2 third transistor

Q3 second transistor

Q6 transistor

S1 switching element

S2 switching element

T3 power supply terminal

T4 control terminal (first control terminal)

T5 control terminal (second control terminal)

Vbat battery voltage

Vcc1 first power supply voltage

Vcc2 second power supply voltage

Vramp control voltage

1. A power amplification circuit configured to amplify a radio-frequency signal, the power amplification circuit comprising:
a driving-stage amplifier comprising a first transistor having a first input terminal, a first output terminal, and a first ground terminal;
a final-stage amplifier comprising a second transistor having a second input terminal, a second output terminal, and a second ground terminal, the second input terminal being connected to the first output terminal;
a power supply terminal;
a first voltage control circuit that is connected between the power supply terminal and the first output terminal, and that that is configured to control a first power supply voltage applied to the first transistor; and
a second voltage control circuit that is a different circuit from the first voltage control circuit, the second voltage control circuit being connected between the power supply terminal and the second output terminal, and configured to control a second power supply voltage applied to the second transistor.

2. The power amplification circuit according to claim 1,
wherein control of the first power supply voltage by the first voltage control circuit is independent of control of the second power supply voltage by the second voltage control circuit.

3. The power amplification circuit according to claim 1,
wherein a first time at which the second voltage control circuit is configured to start applying the second power supply voltage to the second transistor is later than a second time at which the first voltage control circuit is configured to start applying the first power supply voltage to the first transistor.

4. The power amplification circuit according to claim 1,
wherein, at a starting point of an operation of the second transistor, the first power supply voltage applied to the first transistor by the first voltage control circuit is larger than a knee voltage of the first transistor.

5. The power amplification circuit according to claim 1,
wherein the first voltage control circuit is a regulator.

6. The power amplification circuit according to claim 1,
wherein the second voltage control circuit is a low-dropout (LDO) regulator.

7. The power amplification circuit according to claim 1,
wherein the second voltage control circuit is a DC-DC converter.

8. The power amplification circuit according to claim 1, further comprising:
a first bias circuit connected to the first input terminal; and
a second bias circuit connected to the second input terminal.

9. A radio-frequency circuit comprising:
the power amplification circuit according to claim 1; and
a filter configured to pass the radio-frequency signal that is amplified and output by the power amplification circuit.

10. A communication device comprising:
the radio-frequency circuit according to claim 9; and
a signal processing circuit that is configured to output the radio-frequency signal to the radio-frequency circuit.

11. The power amplification circuit according to claim 2,
wherein a first time at which the second voltage control circuit is configured to start applying the second power supply voltage to the second transistor is later than a second time at which the first voltage control circuit is configured to start applying the first power supply voltage to the first transistor.

12. The power amplification circuit according to claim 2,
wherein, at a starting point of an operation of the second transistor, the first power supply voltage applied to the first transistor by the first voltage control circuit is larger than a knee voltage of the first transistor.

13. The power amplification circuit according to claim 3,
wherein, at a starting point of an operation of the second transistor, the first power supply voltage applied to the first transistor by the first voltage control circuit is larger than a knee voltage of the first transistor.

14. The power amplification circuit according to claim 2,
wherein the first voltage control circuit is a regulator.

15. The power amplification circuit according to claim 3,
wherein the first voltage control circuit is a regulator.

16. The power amplification circuit according to claim 4,
wherein the first voltage control circuit is a regulator.

17. The power amplification circuit according to claim 2,
wherein the second voltage control circuit is a low-dropout (LDO) regulator.

18. The power amplification circuit according to claim 2,
wherein the second voltage control circuit is a DC-DC converter.

19. The power amplification circuit according to claim 2, further comprising:
a first bias circuit connected to the first input terminal; and
a second bias circuit connected to the second input terminal.

20. The power amplification circuit according to claim 3, further comprising:
a first bias circuit connected to the first input terminal; and
a second bias circuit connected to the second input terminal.
